(19) United States
(12) Patent Application Publication
(10) Pub. No.: US 2025/0072167 A1
(43) Pub. Date: Feb. 27, 2025

(54) DISPLAY DEVICE

(71) Applicant: Samsung Display Co., LTD., Yongin-si (KR)

(72) Inventors: GUNWOO KO, Yongin-si (KR); JUNG-HYUN CHO, Yongin-si (KR); KANGWOOK HEO, Yongin-si (KR); TAE YONG EOM, Yongin-si (KR); BEOHMROCK CHOI, Yongin-si (KR)

(21) Appl. No.: 18/747,741

(22) Filed: Jun. 19, 2024

(30) Foreign Application Priority Data
Aug. 23, 2023 (KR) 10-2023-0110445

(51) Int. Cl. H01L 33/20; H01L 25/075; H01L 33/10

(52) U.S. Cl. CPC H01L 33/20; H01L 25/0753; H01L 33/10

(57) ABSTRACT

A display device includes a display panel, a first refractive pattern disposed on the display panel, where the first refractive pattern has a first refractive index, has a planar shape including a center portion and a peripheral portion, and defines a plurality of refractive openings in which a first refractive opening whose peripheral portion extends from a side of the center portion and a second refractive opening whose peripheral portion extends from a vertex of the center portion are alternately arranged, and a second refractive layer disposed on the first refractive pattern, where the second refractive layer has a second refractive index less than the first refractive index.

This application claims priority to Korean Patent Application No. 10-2023-0110445, filed on Aug. 23, 2023, and all the benefits accruing therefrom under 35 U.S.C. § 119, the content of which in its entirety is herein incorporated by reference.

### BACKGROUND

### 1. Field

The disclosure relates to a display device, and more particularly to a display device with improved display quality.

### 2. Description of the Related Art

Recently, a display device having desired characteristics such as miniaturization, weight reduction, and low power consumption are widely used in various fields. For example, plasma displays, liquid crystal displays, organic light emitting displays, and quantum dot displays are attracting attention.

Such a display device may include an optical structure to improve light output efficiency. Display quality (e.g., the light output efficiency, etc.) of the display device may vary depending on a shape and an arrangement of the optical structure.

### SUMMARY

The disclosure may provide a display device with improved display quality.

A display device according to embodiments of the disclosure includes a display panel, a first refractive pattern disposed on the display panel, where the first refractive pattern has a first refractive index, has a planar shape including a center portion and a peripheral portion, and defines a plurality of refractive openings in which a first refractive opening whose peripheral portion extends from a side of the center portion and a second refractive opening whose peripheral portion extends from a vertex of the center portion are alternately arranged; and a second refractive layer disposed on the first refractive pattern, where the second refractive layer has a second refractive index smaller than the first refractive index.

In an embodiment, the first refractive opening and the second refractive opening may be alternately arranged in a first direction.

In an embodiment, the first refractive opening and the second refractive opening may be alternately arranged in a second direction crossing the first direction.

In an embodiment, the display panel may include a first pixel disposed on a substrate and a second pixel disposed on the substrate and spaced apart from the first pixel, the first pixel may include first to third sub-pixels which emit light having different colors, respectively, the second pixel may include fourth to sixth sub-pixels which emit light having different colors, respectively, each of the first to third sub-pixels may overlap the first refractive opening, and each of the fourth to sixth sub-pixels may overlap the second refractive opening.

In an embodiment, a pixel opening in which a light emitting element is disposed may be defined in the display panel, the center portion of the plurality of refractive openings may have a polygonal shape including a first long side, a second long side opposite to the first long side, a first short side crossing the first long side and the second long side, and a second short side opposite to the first short side, and the center portion of the plurality of refractive openings may extend in a direction parallel to an extension direction of the first long side and the second long side.

In an embodiment, a minimum distance between a third short side of the pixel opening adjacent to the first short side of the center portion of the plurality of refractive openings in the planar shape of the pixel opening and the first short side of the center portion in the planar shape of the pixel opening may be equal to a minimum distance between a fourth short side of the pixel opening adjacent to the second short side of the center portion of the plurality of refractive openings in the planar shape of the pixel opening and the second short side of the center portion of the plurality of refractive openings.

In an embodiment, a pixel opening, in which a light emitting element is disposed, may be defined in the display panel, the center portion of the plurality of refractive openings may overlap the pixel opening, the center portion of the plurality of refractive openings may have a polygonal shape including a first long side, a second long side opposite to the first long side, a first short side crossing the first long side and the second long side, and a second short side opposite to the first short side, and the center portion of the plurality of refractive openings may extend in a direction parallel to an extension direction of the first short side and the second short side.

In an embodiment, a minimum distance between a third long side of the pixel opening adjacent to the first long side of the center portion of the plurality of refractive openings in the planar shape of the pixel opening and the first long side of the center portion in the planar shape of the pixel opening may be equal to a minimum distance between a fourth long side of the pixel opening adjacent to the second long side of the center portion of the plurality of refractive openings in the planar shape of the pixel opening and the second long side of the center portion of the plurality of refractive openings.

In an embodiment, a pixel opening in which a light emitting element is disposed may be defined in the display panel, a planar shape of the pixel opening may be a polygonal shape with a long side and a short side, the center portion of the plurality of refractive openings may overlap the pixel opening, the center portion of the plurality of refractive openings may have a polygonal shape including a first long side, a second long side opposite to the first long side, a first short side crossing the first long side and the second long side, and a second short side opposite to the first short side, a shape of the center portion of the plurality of refractive openings in the plan view may be arranged in a repeating unit of 4×2 matrix, the center portion located at a first row and a first column, the center portion located at the first row and a fourth column, the center portion located at a second row and a second column, and the center portion located at the second row and a third column may extend in a direction parallel to the long side of the planar shape of the pixel opening, and the center portion located at the first row and the second column, the center portion located at the first row and the third column, the center portion located at the second row and the first column, and the center portion located at the second row and the fourth column may extend in a direction parallel to the short side of the planar shape of the pixel opening.

In an embodiment, a minimum distance between a third short side of the pixel opening adjacent to the first short side of the center portion of the plurality of refractive openings in the planar shape of the pixel opening and the first short side of the center portion in the planar shape of the pixel opening may be equal to a minimum distance between a fourth short side of the pixel opening adjacent to the second short side of the center portion of the plurality of refractive openings in the planar shape of the pixel opening and the second short side of the center portion of the plurality of refractive openings, and a minimum distance between a third long side of the pixel opening adjacent to the first long side of the center portion of the plurality of refractive openings in the planar shape of the pixel opening and the first long side of the center portion in the planar shape of the pixel opening may be equal to a minimum distance between a fourth long side of the pixel opening adjacent to the second long side of the center portion of the plurality of refractive openings in the planar shape of the pixel opening and the second long side of the center portion of the plurality of refractive openings.

A display device according to embodiments of the disclosure includes a display panel including a light emitting element, which is disposed in a pixel opening defined in the display panel, where the pixel opening has a planar shape with a long side and a short side; a first refractive pattern disposed on the display panel, where the first refractive pattern has a first refractive index, overlaps the pixel openings, and defines a plurality of refractive openings including a center portion whose planar shape is a polygonal shape with a first long side, a second long side opposite to the first long side, a first short side crossing the first long side and the second long side, and a second short side opposite to the first short side and a peripheral portion extending from the center portion; and a second refractive layer disposed on the first refractive pattern, where the second refractive layer has a second refractive index less than the first refractive index. In such embodiments, a shape of the center portion of the plurality of refractive openings in a plan view may be arranged in a repeating unit of 4×2 matrix, the center portion located at a first row and a first column, the center portion located at the first row and a fourth column, the center portion located at a second row and a second column, and the center portion located at the second row and a third column may extend in a direction parallel to the long side of the planar shape of the pixel opening, and the center portion located at the first row and the second column, the center portion located at the first row and the third column, the center portion located at the second row and the first column, and the center portion located at the second row and the fourth column may extend in a direction parallel to the short side of the planar shape of the pixel opening.

In an embodiment, the first refractive pattern may include a first refractive opening whose peripheral portion extends from a side of the center portion and a second refractive opening whose peripheral portion extends from a vertex of the center portion in the plan view, and the first refractive opening and the second refractive opening may be alternately arranged located in a first direction.

In an embodiment, the first refractive pattern may include a first refractive opening whose peripheral portion extends from a side of the center portion and a second refractive opening whose peripheral portion extends from a vertex of the center portion in the plan view, and the first refractive opening and the second refractive opening may be alternately arranged in a second direction crossing a first direction.

In an embodiment, a minimum distance between a third short side of the pixel opening adjacent to the first short side of the center portion of the plurality of refractive openings in the planar shape of the pixel opening and the first short side of the center portion in the planar shape of the pixel opening may be equal to a minimum distance between a fourth short side of the pixel opening adjacent to the second short side of the center portion of the plurality of refractive openings in the planar shape of the pixel opening and the second short side of the center portion of the plurality of refractive openings, and a minimum distance between a side of the pixel opening adjacent to the first long side of the center portion of the plurality of refractive openings in the planar shape of the pixel opening and the first long side of the center portion in the planar shape of the pixel opening may be equal to a minimum distance between a side of the pixel opening adjacent to the second long side of the center portion of the plurality of refractive openings in the planar shape of the pixel opening and the second long side of the center portion of the plurality of refractive openings.

In an embodiment, the display panel may include a first pixel disposed on a substrate and a second pixel disposed on the substrate and spaced apart from the first pixel, the first pixel may include first to third sub-pixels which emit light having different colors, respectively, the second pixel may include fourth to sixth sub-pixels which emit light having different colors, respectively, the peripheral portion of the plurality of refractive openings overlapping each of the first to third sub-pixels may extend from a side of the center portion, and the peripheral portion of the plurality of refractive openings overlapping each of the fourth to sixth sub-pixels may extend from a vertex of the center portion.

A display device according to embodiments of the disclosure includes a display panel; a first refractive pattern disposed on the display panel, where the first refractive pattern has a first refractive index, and defines a plurality of refractive openings including a center portion whose planar shape is a polygonal shape with a first long side, a second long side opposite to the first long side, a first short side crossing the first long side and the second long side, and a second short side opposite to the first short side and a peripheral portion extending from the center portion; and a second refractive layer disposed on the first refractive pattern, where the second refractive layer has a second refractive index less than the first refractive index. In such embodiments, a shape of the center portion of the plurality of refractive openings in a plan view may be arranged in a repeating unit of 2×2 matrix, the center portion located at a first row and a first column, and the center portion located at a second row and a second column may extend in a direction parallel to an extension direction of the first long side and the second long side, and the center portion located at the first row and the second column, and the center portion located at the second row and the first column may extend in a direction parallel to an extension direction of the first short side and the second short side.

In an embodiment, the first refractive pattern may include a first refractive opening whose peripheral portion extends from a side of the center portion and a second refractive opening whose peripheral portion extends from a vertex of the center portion in the plan view, and the first refractive opening and the second refractive opening may be alternately arranged in a first direction.

In an embodiment, the first refractive pattern may include a first refractive opening whose peripheral portion extends from a side of the center portion and a second refractive opening whose peripheral portion extends from a vertex of the center portion in the plan view, and the first refractive opening and the second refractive opening may be alternately arranged in a second direction crossing a first direction.

In an embodiment, a pixel opening in which a light emitting element is disposed may be defined in the display panel, a minimum distance between a third short side of the pixel opening adjacent to the first short side of the center portion of the plurality of refractive openings and the first short side of the center portion in the planar shape of the pixel opening may be equal to a minimum distance between a fourth short side of the pixel opening adjacent to the second short side of the center portion of the plurality of refractive openings and the second short side of the center portion of the plurality of refractive openings in the planar shape of the pixel opening, and a minimum distance between a third long side of the pixel opening adjacent to the first long side of the center portion of the plurality of refractive openings and the first long side of the center portion in the planar shape of the pixel opening may be equal to a minimum distance between a fourth long side of the pixel opening adjacent to the second long side of the center portion of the plurality of refractive openings and the second long side of the center portion of the plurality of refractive openings in the planar shape of the pixel opening.

In an embodiment, the display panel may include a first pixel disposed on a substrate and a second pixel disposed on the substrate and spaced apart from the first pixel, the first pixel may include first to third sub-pixels which emit light having different colors, respectively, the second pixel may include fourth to sixth sub-pixels which emit light having different colors, respectively, the peripheral portion of the plurality of refractive openings overlapping each of the first to third sub-pixels may extend from a side of the center portion, and the peripheral portion of the plurality of refractive openings overlapping each of the fourth to sixth sub-pixels may extend from a vertex of the center portion.

As described above, according to embodiments, a display device includes a display panel, a first refractive pattern disposed on the display panel, where the first refractive pattern has a first refractive index, has a planar shape including a center portion and a peripheral portion, and defines a plurality of refractive openings in which a first refractive opening whose peripheral portion extends from a side of the center portion and a second refractive opening whose peripheral portion extends from a vertex of the center portion are alternately arranged; and a second refractive layer disposed on the first refractive pattern, where the second refractive layer has a second refractive index less than the first refractive index. Accordingly, front light efficiency of the display device may be enhanced and occurrence of a diagonal spot may be effectively prevented.

### BRIEF DESCRIPTION OF THE DRAWINGS

Illustrative, non-limiting embodiments will be more clearly understood from the following detailed description in conjunction with the accompanying drawings.

FIG. 1 and FIG. 2 are views illustrating a display panel, according to an embodiment.

FIG. 3 is a plan view illustrating an area A of FIG. 2.

FIG. 4 is a sectional view taken along lines I-I′, II-II′, and III-III′ of FIG. 3.

FIG. 5 is an enlarged view of the light control layer included in the display device of FIG. 4.

FIG. 6 is a plan view illustrating the refractive opening of the first refractive pattern of FIG. 3 according to an embodiment.

FIG. 7 is a plan view illustrating a refractive opening of a first refraction pattern of FIG. 3 according to another embodiment.

FIG. 8 is a plan view illustrating a refractive opening of a first refraction pattern of FIG. 3 according to another embodiment.

FIGS. 9 to 18 are views illustrating an arrangement structure of refractive openings of the first refractive pattern.

FIG. 19 is a view illustrating an arrangement structure of refractive openings of a first refractive pattern according to a comparative example.

### DETAILED DESCRIPTION

The invention now will be described more fully hereinafter with reference to the accompanying drawings, in which various embodiments are shown. The invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a” “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

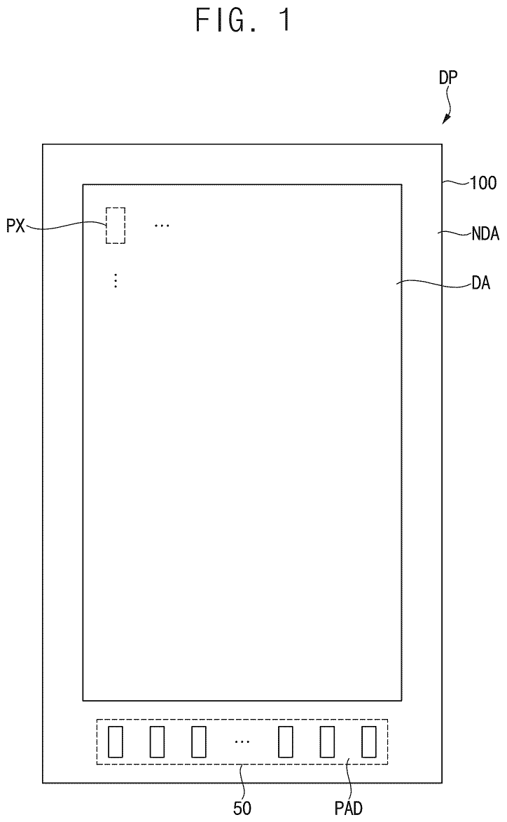

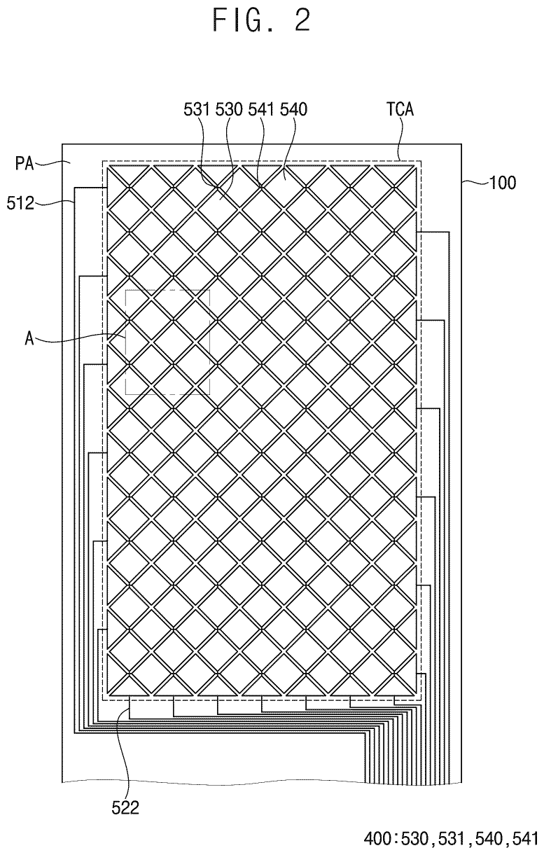

FIG. 1 and FIG. 2 are views illustrating a display panel, according to an embodiment.

Hereinafter, FIGS. 1 and 2 are views illustrating a display panel according to embodiments of the disclosure.

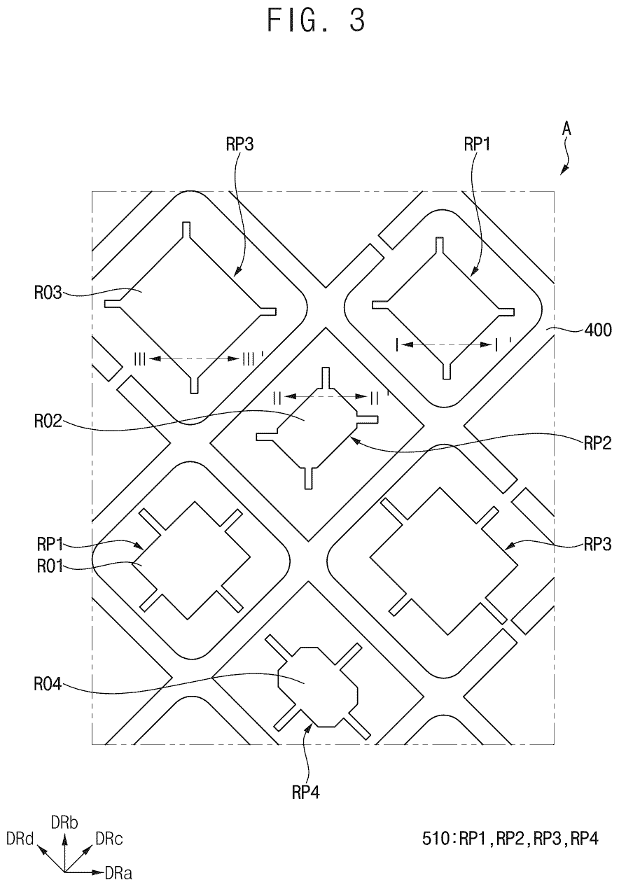

For example, FIG. 1 is a plan view illustrating a display panel DP, and FIG. 2 is a plan view illustrating a sensing layer (for example, a sensing layer 400 of FIG. 3) included in the display panel DP.

Referring to FIG. 1, an embodiment of the display panel DP may include a substrate 100 and a pad portion 50.

The substrate 100 may include a display area DA and a non-display area NDA.

The display area DA may mean an area for displaying an image. In an embodiment, a plurality of pixels PX including a transistor, a light emitting diode (LED), or the like may be disposed in the display area DA.

The pixels PX may be arranged in a matrix form along a row direction and a column direction. Each of the pixels PX may mean a single area defined by partitioning the display area in the plan view for color display. Each of the pixels PX may be a minimum or basic unit capable of displaying an independent color. The display panel DP may display an image by a combination of lights emitted from each of the plurality of pixels PX in the display area DA.

The non-display area NDA may mean an area in which an image is not displayed. The non-display area NDA may be adjacent to the display area DA. In an embodiment, for example, the non-display area NDA may surround the display area DA. However, the disclosure is not limited thereto. In an embodiment, for example, the non-display area NDA may surround only a part of the display area DA.

Pads PAD for applying a driving signal to the pixels PX may be disposed in the non-display area NDA.

Referring to FIGS. 1 and 2, in an embodiment, a sensing area TCA may be located to overlap the display area DA. However, the disclosure is not limited thereto. In an embodiment, for example, the sensing area TCA may be located to overlap the display area DA and a part of the non-display area NDA. In such embodiments, the position of the sensing area TCA may be variously changed.

A plurality of sensing electrodes 530 and 540 may be disposed in the sensing area TCA. In an embodiment, for example, the plurality of sensing electrodes 530 and 540 may be disposed on a plurality of pixels PX. In such an embodiment, the plurality of pixels PX may be disposed on the substrate 100, and the plurality of sensing electrodes 530 and 540 may be disposed on the plurality of pixels PX. However, the disclosure is not limited thereto. For example, a touch sensor or the like may be further disposed in the sensing area TCA.

The plurality of sensing electrodes 530 and 540 may include a first sensing electrode 530 and a second sensing electrode 540.

The first sensing electrode 530 and the second sensing electrode 540 may be electrically separated from each other. In an embodiment, for example, the first sensing electrode 530 may be a sensing input electrode, and the second sensing electrode 540 may be a sensing output electrode. However, the disclosure is not limited thereto. In an embodiment, for example, the first sensing electrode 530 may be a sensing output electrode, and the second sensing electrode 540 may be a sensing input electrode.

The first sensing electrode 530 and the second sensing electrode 540 may be disposed in a mesh shape in the sensing area TCA. A plurality of first sensing electrodes 530 may be disposed along the column direction and the row direction, and a plurality of second sensing electrodes 540 may be disposed along the column direction and the row direction.

The first sensing electrode 530 and the second sensing electrode 540 may be disposed in (or directly on) a same layer as each other. However, the disclosure is not limited thereto. In an embodiment, for example, the first sensing electrode 530 and the second sensing electrode 540 may be located in different layers from each other.

The first sensing electrode 530 and the second sensing electrode 540 may have a rhombus shape. However, the disclosure is not limited thereto. The first sensing electrode 530 and the second sensing electrode 540 may have various shapes. In an embodiment, for example, the first sensing electrode 530 and the second sensing electrode 540 may have a polygonal shape such as a quadrangular shape, a hexagonal shape, or the like, or a circular shape, an oval shape, or the like.

The first sensing electrode 530 and the second sensing electrode 540 may include a transparent conductor or an opaque conductor. In an embodiment, for example, the first sensing electrode 530 and the second sensing electrode 540 may include a transparent conductive oxide (TCO). The transparent conductive oxide may include indium tin oxide (ITO), indium zinc oxide (IZO), zinc oxide (ZnO), carbon nanotube (CNT), graphene, or the like. These may be used alone or in combination with each other.

A plurality of refractive openings may be defined in the first sensing electrode 530 and the second sensing electrode 540. The plurality of refractive openings defined in the plurality of sensing electrodes 530 and 540 may serve to allow light emitted from the light emitting diode to be emitted to a front surface without interference.

The plurality of first sensing electrodes 530 may be electrically connected to each other by a first sensing electrode connection portion 531, and the plurality of second sensing electrodes 540 may be electrically connected to each other by a second sensing electrode connection portion 541. In an embodiment, for example, the first sensing electrodes 530 may be connected to each other in the column direction by the first sensing electrode connection portion 531, and the plurality of second sensing electrodes 540 may be connected to each other in the row direction by the second sensing electrode connection portion 541.

In an embodiment where the first sensing electrode 530 and the second sensing electrode 540 are located in (or directly on) a same layer as each other, one of the first sensing electrode connection portion 531 and the second sensing electrode connection portion 541 may be located in (or directly on) the same layer as the first sensing electrode 530 and the second sensing electrode 540, and the other may be located in (or directly on) a different layer from the first sensing electrode 530 and the second sensing electrode 540. Accordingly, the first sensing electrode 530 and the second sensing electrode 540 may be electrically separated from each other.

The sensing electrode connection portion (for example, the first sensing electrode connection portion 531 or the second sensing electrode connection portion 541) located in the different layer may be located in a lower layer of the first sensing electrode 530 and the second sensing electrode 540. In an embodiment, for example, the sensing electrode connection portion may be disposed on the substrate 100, and the first sensing electrode 530 and the second sensing electrode 540 may be disposed on the sensing electrode connection portion. However, the disclosure is not limited thereto. In an embodiment, for example, the sensing electrode connection portion (for example, the first sensing electrode connection portion 531 or the second sensing electrode connection portion 541) located on the different layer may be located on an upper layer of the first sensing electrode 530 and the second sensing electrode 540. In an embodiment, for example, the first sensing electrode 530 and the second sensing electrode 540 may be disposed on the substrate 100, and the sensing electrode connection portion may be disposed on the first sensing electrode 530 and the second sensing electrode 540.

A plurality of voltage lines (for example, a driving voltage line, a driving low-voltage line, etc.) for transmitting a driving signal (for example, a voltage, etc.) to the pixels PX disposed in the display area DA may be disposed in the non-display area NDA. In addition, a plurality of sensing wires 512 and 522 may be disposed in the non-display area NDA. The plurality of sensing wires 512 and 522 may be connected to the plurality of sensing electrodes 530 and 540.

As described above, the pad portion 50 may be disposed in the non-display area NDA. In an embodiment, for example, the pad portion 50 may be located in a part of the non-display area NDA. A plurality of pads PAD may be disposed in the pad portion 50.

A flexible printed circuit board (FPCB) may be attached to the non-display area NDA. The flexible printed circuit board may be electrically connected to the pad portion 50. A driving integrated circuit may be disposed on the flexible printed circuit board. The driving integrated circuit may output a driving signal, and the driving signal may be applied to the plurality of voltage wires the plurality of sensing wires 512 and 522, or the like connected to the display area DA through the plurality of pads PAD included in the pad portion 50, and may be supplied to the plurality of pixels PX.

The plurality of sensing wires 512 and 522 may include a first sensing wire 512 and a second sensing wire 522. The first sensing wire 512 may be connected to the second sensing electrode 540 disposed in the row direction, and the second sensing wire 522 may be connected to the first sensing electrode 530 disposed in the column direction. In an embodiment, for example, the first sensing wire 512 and the second sensing wire 522 may be electrically connected to a part of the plurality of pads PAD included in the pad portion 50.

In an embodiment, as described above, the sensing layer may be a mutual-cap type in which a touch is sensed using the first sensing electrode 530 and the second sensing electrode 540, the disclosure is not limited thereto. In an embodiment, for example, the sensing layer may be a self-cap type. In an embodiment where the sensing layer is the self-cap type, the touch may be sensed using only one sensing electrode.

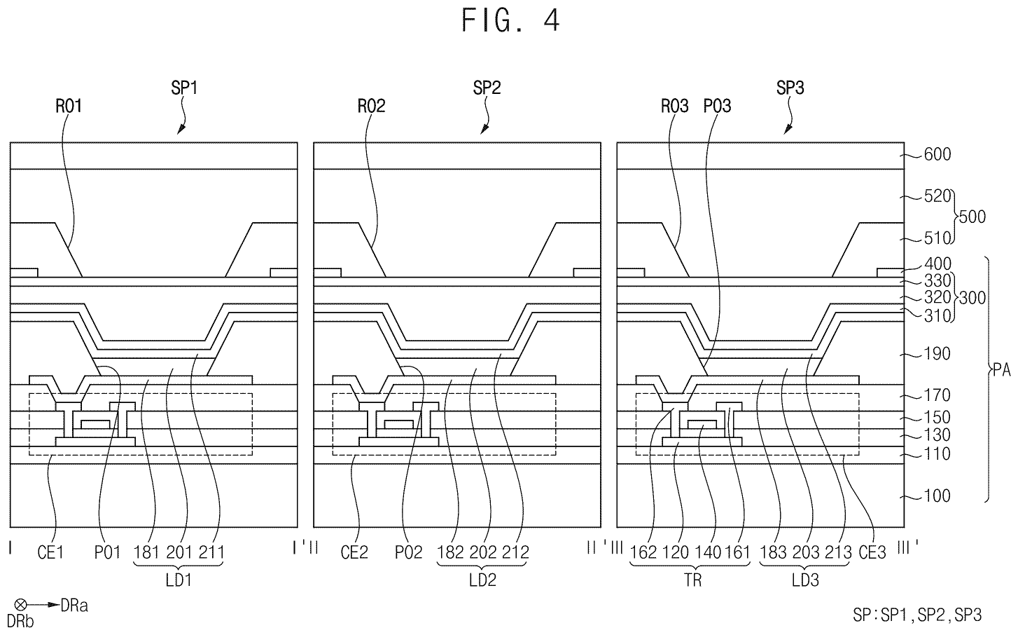

FIG. 3 is a plan view illustrating an area A of FIG. 2. FIG. 4 is a sectional view taken along lines I-I′, II-II′, and III-III′ of FIG. 3.

Referring to FIGS. 1, 3, and 4, in an embodiment, the display device may include a display panel PA, a light control layer 500, and a window 600. The display panel PA may include the substrate 100, first to third circuit elements CE1, CE2, and CE3, first to third light emitting elements LD1, LD2, and LD3, a thin film encapsulation layer 300, and a sensing layer 400.

Each of the plurality of pixels PX included in the display panel PA may include a plurality of sub-pixels SP. In an embodiment, for example, the plurality of sub-pixels SP may include a first sub-pixel SP1, a second sub-pixel SP2, and a third sub-pixel SP3. In an embodiment, for example, each of the pixels PX may include one first sub-pixel SP1, two second sub-pixels SP2, and one third sub-pixel SP3. In such an embodiment, the first to third sub-pixels SP1, SP2, and SP3 may be arranged in a pentile matrix shape.

However, the disclosure is not limited thereto. In an embodiment, for example, each of the pixels PX may include one first sub-pixel SP1, one second sub-pixel SP2, and one third sub-pixel SP3. In such an embodiment, the first to third sub-pixels SP1, SP2, and SP3 may be arranged in a stripe shape.

The first sub-pixel SP1, the second sub-pixel SP2, and the third sub-pixel SP3 may emit light having different colors, respectively. In an embodiment, for example, the first sub-pixel SP1, the second sub-pixel SP2, and the third sub-pixel SP3 may be a red sub-pixel that emits red light, a green sub-pixel that emits green light, and a blue sub-pixel that emits blue light, respectively. Each of the pixels PX may emit light having various colors by adjusting the luminance of light emitted from each of the first sub-pixel SP1, the second sub-pixel SP2, and the third sub-pixel SP3.

The first sub-pixel SP1 may include the first circuit element CE1 and the first light emitting element LD1. The first light emitting element LD1 may be electrically connected to the first circuit element CE1.

The second sub-pixel SP2 may include the second circuit element CE2 and the second light emitting element LD2. The second light emitting element LD2 may be electrically connected to the second circuit element CE2.

The third sub-pixel SP3 may include the third circuit element CE3 and the third light emitting element LD3. The third light emitting element LD3 may be electrically connected to the third circuit element CE3.

Each of the first circuit electrode CE1, the second circuit element CE2, and the third circuit electrode CE3 may include a transistor TR. However, the disclosure is not limited thereto. In an embodiment, for example, each of the first circuit element CE1, the second circuit element CE2, and the third circuit element CE3 may further include a capacitor CAP.

The substrate 100 may be an insulating substrate including glass, quartz, plastic, or the like. In an embodiment, for example, the substrate 100 may be a flexible substrate. In this case, the substrate 100 may include a polymer resin. In an embodiment, for example, the substrate 100 may include polycarbonate (PC), polymethyl methacrylate (PMMA), polyarylate (PAR), polyethersulfone (PES), polyethylene terephthalate (PET), polyethylene naphthalate (PEN), or the like. However, the disclosure is not limited thereto.

A buffer layer 110 may be disposed on the substrate 100. The buffer layer 110 may block impurities such as oxygen and moisture penetrating through the substrate 100. In addition, the buffer layer 110 may provide a flat surface on the substrate 100. In an embodiment, the buffer layer 110 may include an inorganic insulating material. In an embodiment, for example, the buffer layer 110 may include silicon nitride, silicon oxide, silicon oxynitride, or the like. However, the disclosure is not limited thereto. Alternatively, the buffer layer 110 may be omitted.

A semiconductor layer 120 may be disposed on the buffer layer 110. The semiconductor layer 120 may include or be formed of amorphous silicon, polycrystalline silicon, an oxide semiconductor, or the like. In an embodiment, for example, where the semiconductor layer 120 include or is formed of polycrystalline silicon, the semiconductor layer 120 may include a channel area which is not doped with impurities, and a source area and a drain area which are formed by doping impurities on both sides of the channel area. In such an embodiment, the impurities may be P-type impurities such as boron (B). For example, the P-type impurities may be B₂H₆. However, the disclosure is not limited thereto. The impurities may vary depending on the type of the transistor TR. In addition, the transistor TR may have various structures. In an embodiment, for example, the transistor TR may have a N-channel metal-oxide semiconductor (NMOS) structure or a P-channel metal-oxide semiconductor (CMOS) structure.

A first insulating layer 130 may be disposed on the semiconductor layer 120. The first insulating layer 130 may be disposed on the buffer layer 110 while covering the semiconductor layer 120. In an embodiment, the first insulating layer 130 may include an inorganic insulating material. In an embodiment, for example, the first insulating layer 130 may include silicon nitride, silicon oxide, silicon oxynitride, or the like. These may be used alone or in combination with each other.

A gate electrode 140 may be disposed on the first insulating layer 130. The gate electrode 140 may overlap the channel area of the semiconductor layer 120. The gate electrode 140 may include or be formed of molybdenum (Mo), chromium (Cr), tungsten (W), or the like. These may be used alone or in combination with each other.

A second insulating layer 150 may be disposed on the gate electrode 140. The second insulating layer 150 may be disposed on the first insulating layer 130 while covering the gate electrode 140. In an embodiment, the second insulating layer 150 may include an inorganic insulating layer. In an embodiment, for example, the second insulating layer 150 may include silicon nitride, silicon oxide, silicon oxynitride, or the like. These may be used alone or in combination with each other.

A source electrode 161 and a drain electrode 162 may be disposed on the second insulating layer 150. The source electrode 161 and the drain electrode 162 may make contact with the source area and the drain area of the semiconductor layer 120, respectively, through contact holes formed through the first insulating layer 130 and the second insulating layer 150. In an embodiment, for example, the source electrode 161 and the drain electrode 162 may include or be formed of aluminum (Al), titanium (Ti), chromium (Cr), tungsten (W), or the like. These may be used alone or in combination with each other.

Accordingly, the semiconductor layer 120, the gate electrode 140, the source electrode 161, and the drain electrode 162 may form the transistor TR.

A planarization layer 170 may be disposed on the source electrode 161 and the drain electrode 162. The planarization layer 170 may be disposed on the second insulating layer 150 while covering the source electrode 161 and the drain electrode 162. The planarization layer 170 may provide a flat surface on the source electrode 161 and the drain electrode 162. In an embodiment, the planarization layer 170 may include an organic insulating material. In an embodiment, for example, the planarization layer 170 may include an acryl-based resin, an epoxy-based resin, a polyimide-based resin, a polyester-based resin, or the like. In an embodiment, the planarization layer 170 may include an inorganic insulating material. In an embodiment, for example, the planarization layer 170 may include silicon nitride, silicon oxide, silicon oxynitride, or the like. These may be used alone or in combination with each other.

The first light emitting element LD1, the second light emitting element LD2, and the third light emitting element LD3 may be disposed on the planarization layer 170. The first light emitting element LD1 may include a first pixel electrode 181, a first light emitting layer 201, and a first counter electrode 211, the second light emitting element LD2 may include a second pixel electrode 182, a second light emitting layer 202, and a second counter electrode 212, and the third light emitting element LD3 may include a third pixel electrode 183, a third light emitting layer 203, and a third counter electrode 213.

The first pixel electrode 181, the second pixel electrode 182, and the third pixel electrode 183 may be disposed on the planarization layer 170. The first pixel electrode 181, the second pixel electrode 182, and the third pixel electrode 183 may be electrically connected to the first circuit element CE1, the second circuit element CE2, and the third circuit element CE3, respectively, through contact holes defined or formed in the planarization layer 170. The first to third pixel electrodes 181, 182, and 183 may be individually formed in first to third sub-pixels SPX1, SPX2, and SPX3, respectively. In other words, the first to third pixel electrodes 181, 182, and 183 may be separated from each other.

A pixel defining layer 190 may be disposed on the first pixel electrode 181, the second pixel electrode 182, and the third pixel electrode 183. The pixel defining layer 190 may be formed on the planarization layer 170 while covering the first pixel electrode 181, the second pixel electrode 182, and the third pixel electrode 183. In an embodiment, the pixel defining layer 190 may include an organic material. In an embodiment, for example, the pixel defining layer 190 may include polyimide (PI), hexamethyldisiloxane (HMDSO), or the like. These may be used alone or in combination with each other.

The pixel defining layer 190 may define a first pixel opening PO1, a second pixel opening PO2, and a third pixel opening PO3 which expose at least a part of the first pixel electrode 181, at least a part of the second pixel electrode 182, and at least a part of the third pixel electrode 183, respectively. In an embodiment, for example, the first pixel opening PO1, the second pixel opening PO2, and the third pixel opening PO3 may expose a center portion of the first pixel electrode 181, a center portion of the second pixel electrode 182, and a center portion of the third pixel electrode 183, respectively, and the pixel defining layer 190 may cover a peripheral portion of the first pixel electrode 181, a peripheral portion of the second pixel electrode 182, and a peripheral portion of the third pixel electrode 183. The pixel defining layer 190 may define a first pixel opening PO1, a second pixel opening PO2, and a third pixel opening PO3 to define the first to third sub-pixels SPX1, SPX2, and SPX3.

The size of the first pixel opening PO1, the size of the second pixel opening PO2, and the size of the third pixel opening PO3 may be different from each other. In an embodiment, for example, the size of the second pixel opening PO2 may be smaller than the size of the first pixel opening PO1, and the size of the third pixel opening PO3 may be larger than the size of the first pixel opening PO1. However, the disclosure is not limited thereto.

The first light emitting layer 201 may be disposed in the first pixel opening PO1 on the first pixel electrode 181, the second light emitting layer 202 may be disposed in the second pixel opening PO2 on the second pixel electrode 182, and the third light emitting layer 203 may be disposed in the third pixel opening PO3 on the third pixel electrode 183. Each of the first light emitting layer 201, the second light emitting layer 202, and the third light emitting layer 203 may include at least one selected from an organic light emitting material and a quantum dot.

In an embodiment, for example, the organic light emitting material may include a low molecular weight organic compound or a high molecular weight organic compound. The low molecular weight organic compound may include copper phthalocyanine, N,N′-diphenylbenzidine, tris-(8-hydroxyquinoline)aluminum, or the like, and the high molecular weight organic compound may include poly(3,4-ethylenedioxythiophene), polyaniline, poly-phenylenevinylene, polyfluorene, or the like. These may be used alone or in combination with each other.

In an embodiment, for example, the quantum dot may include a core including a Group II-VI compound, a Group III-V compound, a Group IV-VI compound, a Group IV element, a Group IV compound, and a combination thereof. These may be used alone or in combination with each other. In an embodiment, for example, the quantum dot may have a core-shell structure including a core and a shell surrounding the core. The shell may serve as a protective layer for preventing chemical denaturation of the core to maintain semiconductor characteristics. and may serve as a charging layer for imparting electrophoretic characteristics to the quantum dot.

The first light emitting layer 201, the second light emitting layer 202, and the third light emitting layer 203 may emit light having different colors, respectively. In an embodiment, for example, the first light emitting layer 201, the second light emitting layer 202, and the third light emitting layer 203 may emit red light, green light, and blue light, respectively.

The first counter electrode 211, the second counter electrode 212, and the third counter electrode 213 may be arranged on the first light emitting layer 201, the second light emitting layer 202, and the third light emitting layer 203, respectively. In an embodiment, the first to third counter electrodes 211, 212, and 213 may be commonly formed in the first to third sub-pixels SPX1, SPX2, and SPX3. In such an embodiment, the first to third counter electrodes 211, 212, and 213 may be connected to each other.

Light generated in the first light emitting layer 201 may be emitted in a direction from the first pixel electrode 181 toward the first counter electrode 211, light generated in the second light emitting layer 202 may be emitted in a direction from the second pixel electrode 182 toward the second counter electrode 212, and light generated in the third light emitting layer 203 may be emitted in a direction from the third pixel electrode 183 toward the third counter electrode 213. In this case, each of the first pixel electrode 181, the second pixel electrode 182, and the third pixel electrode 183 may include or be formed of a reflective layer, and each of the first counter electrode 211, the second counter electrode 212, and the third counter electrode 213 may include or be formed of a semi-transmissive layer or a transmissive layer. The semi-transmissive layer and the transmissive layer may be classified according to a thickness.

In an embodiment, for example, the transmissive layer and the semi-transmissive layer may include at least one metal selected from magnesium (Mg), silver (Ag), gold (Au), calcium (Ca), lithium (Li), chromium (Cr), and aluminum (Al), or an alloy thereof. These may be used alone or in combination with each other.

For example, the transmissive layer may include indium tin oxide (ITO), indium zinc oxide (IZO), zinc oxide (ZnO), indium oxide (In₂O₃), or the like. These may be used alone or in combination with each other.

The pixel defining layer 190 may cover the peripheral portion of each of the first to third pixel electrodes 181, 182, and 183, and the first to third light emitting layers 201, 202, and 203 and the first to third counter electrodes 211, 212, and 213 may be disposed in the first to third pixel openings PO1, PO2, and PO3, respectively. Accordingly, the pixel defining layer 190 may surround the first to third light emitting elements LD1, LD2, and LD3. In an embodiment, the pixel defining layer 190 may have a lattice shape surrounding the first to third sub-pixels SPX1, SPX2, and SPX3 in the plan view.

The thin film encapsulation layer 300 may be disposed on the first counter electrode 211, the second counter electrode 212, and the third counter electrode 213. The thin film encapsulation layer 300 may cover the first to third light emitting elements LD1, LD2, and LD3 to protect the first to third light emitting elements LD1, LD2, and LD3 from impurities such as external moisture and oxygen.

In an embodiment, the thin film encapsulation layer 300 may include at least one inorganic encapsulation layer and at least one organic encapsulation layer. In an embodiment, for example, the thin film encapsulation layer 300 may include a first inorganic encapsulation layer 310, an organic encapsulation layer 320, and a second inorganic encapsulation layer 330.

The first inorganic encapsulation layer 310 may be disposed on the first counter electrode 211, the second counter electrode 212, and the third counter electrode 213. In an embodiment, for example, the first inorganic encapsulation layer 310 may include aluminum oxide (Al₂O₃), silicon nitride (SiNx), silicon oxide (SiO₂), or the like. These may be used alone or in combination with each other. The first inorganic encapsulation layer 310 may be formed along a profile of the first to third counter electrodes 211, 212, and 213.

The organic encapsulation layer 320 may be disposed on the first inorganic encapsulation layer 310. In an embodiment, for example, the organic encapsulation layer 320 may include epoxy, acrylate, urethane acrylate, or the like. These may be used alone or in combination with each other. The organic encapsulation layer 320 may have a flat top surface, and accordingly, the organic encapsulation layer 320 may serve to planarize upper portions of the first to third light emitting elements LD1, LD2, and LD3.

The second inorganic encapsulation layer 330 may be disposed on the organic encapsulation layer 320. In an embodiment, the second inorganic encapsulation layer 330 may be formed on the first inorganic encapsulation layer 310 while covering the organic encapsulation layer 320. An edge of the second inorganic encapsulation layer 330 may make contact with an edge of the first inorganic encapsulation layer 310. In an embodiment, for example, the second inorganic encapsulation layer 330 may include aluminum oxide (Al₂O₃), silicon nitride (SiNx), silicon oxide (SiO₂), or the like. These may be used alone or in combination with each other. Since the second inorganic encapsulation layer 330 is formed on the organic encapsulation layer 320 having a flat upper surface, a flat upper surface may be provided thereon. In an embodiment, for example, the second inorganic encapsulation layer 330 may include substantially a same material as the first inorganic encapsulation layer 310.

The sensing layer 400 may be disposed on the thin film encapsulation layer 300. In an embodiment, as described above with reference to FIGS. 1 and 2, the sensing layer 400 may sense an external input (for example, an external object making contact with or approaching the sensing layer 400).

In an embodiment, for example, the sensing layer 400 may include a low-resistance metal such as silver (Ag), aluminum (Al), copper (Cu), chromium (Cr), nickel (Ni), or the like, or may include a conductive nanomaterial such as a silver nanowire, a carbon nanotube, or the like. These may be used alone or in combination with each other.

The sensing layer 400 may overlap the pixel defining layer 190, and may not overlap the first to third light emitting layers 201, 202, and 203. Accordingly, the light emitted from the first to third light emitting layers 201, 202, and 203 may be effectively prevented from being substantially reduced or affected by the sensing layer 400.

In an embodiment, the sensing layer 400 may include a sensing electrode that outputs a sensing signal corresponding to an external input to a sensing drive portion and a driving electrode that receives a driving signal from the sensing drive portion. In an embodiment, for example, a part of the sensing layer 400 may be the sensing electrode, and another part of the sensing layer 400 may be the driving electrode.

The light control layer 500 may be disposed on the sensing layer 400. In an embodiment, for example, the light control layer 500 may include a first refractive pattern 510 and a second refractive pattern 520.

The first refractive pattern 510 may be disposed on the sensing layer 400. In an embodiment, the first refractive pattern 510 may be formed on the thin film encapsulation layer 300 while covering the sensing layer 400. The first refractive pattern 510 may have a first refractive index that is a relatively low refractive index.

The first refractive pattern 510 may define a first refractive opening RO1, a second refractive opening RO2, and a third refractive opening RO3. The first refractive opening RO1, the second refractive opening RO2, and the third refractive opening RO3 may overlap the first pixel opening PO1, the second pixel opening PO2, and the third pixel opening PO3, respectively. In this case, the first refractive pattern 510 may overlap the pixel defining layer 190. In an embodiment, for example, the first refractive pattern 510 may have a lattice shape overlapping the pixel defining layer 190 in the plan view. The first to third refractive openings RO1, RO2, and RO3 may expose an upper surface of the thin film encapsulation layer 300.

In an embodiment, for example, the first refractive opening RO1 may have substantially the same shape as the shape of the first pixel opening PO1 in a plan view, the second refractive opening RO2 may have substantially the same shape as the shape of the second pixel opening PO2 in the plan view, and the third refractive opening RO3 may have substantially the same shape as the shape of the third pixel opening PO3 in the plan view.

In an embodiment, for example, the size of the first refractive opening RO1, the size of the second refractive opening RO2, and the size of the third refractive opening RO3 may be larger than the size of the first pixel opening PO1, the size of the second pixel opening PO2, and the size of the third pixel opening PO3, respectively. In this case, an edge of the first refractive opening RO1, an edge of the second refractive opening RO2, and an edge of the third refractive opening RO3 may surround an edge of the first pixel opening PO1, an edge of the second pixel opening PO2, and an edge of the third pixel opening PO3, respectively.

However, the disclosure is not limited thereto. In another embodiment, the size of the first refractive opening RO1, the size of the second refractive opening RO2, and the size of the third refractive opening RO3 may be smaller than the size of the first pixel opening PO1, the size of the second pixel opening PO2, and the size of the third pixel opening PO3, respectively. In such an embodiment, the edge of the first pixel opening PO1, the edge of the second pixel opening PO2, and the edge of the third refractive opening PO3 may surround the edge of the first refractive opening RO1, the edge of the second refractive opening RO2, and the edge of the third refractive opening RO3, respectively. However, the disclosure is not limited thereto.

In an embodiment, for example, the first refractive pattern 510 may include a photoresist. The photoresist may be applied on the thin film encapsulation layer 300 on which the sensing layer 400 is disposed, and may be patterned by exposure and development, and then the first refractive pattern 510 having the first to third refractive openings RO1, RO2, and RO3 may be formed by using photocuring or the like. Through the photocuring, the chemical resistance of the first refractive pattern 510 may increase, and outgas generated in the first refractive pattern 510 may decrease.

The second refractive layer 520 may be disposed on the first refractive pattern 510. In an embodiment, the second refractive layer 520 may be formed on the thin film encapsulation layer 300 while covering the first refractive pattern 510. The second refractive layer 520 may have a second refractive index that is a relatively high refractive index.

In an embodiment, a difference between the second refractive index of the second refractive layer 520 and the first refractive index of the first refractive pattern 510 may be about 0.15 or greater. In such an embodiment, a value obtained by subtracting the first refractive index from the second refractive index may be about 0.15 or greater. In an embodiment, for example, the first refractive index may be about 1.5, and the second refractive index may be about 1.65 or greater. However, the disclosure is not limited thereto.

When the difference between the second refractive index of the second refractive layer 520 and the first refractive index of the first refractive pattern 510 is less than about 0.15, front light efficiency may rapidly decrease. Accordingly, in an embodiment, the difference between the second refractive index of the second refractive layer 520 and the first refractive index of the first refractive pattern 510 may be about 0.15 or greater, such that the front light efficiency of the display device may increase.

In an embodiment, the second refractive layer 520 may fill the first to third refractive openings RO1, RO2, and RO3 of the first refractive pattern 510. In such an embodiment, the second refractive layer 520 may overlap the first to third light emitting elements LD1, LD2, and LD3 and the pixel defining layer 190. An upper surface of the second refractive layer 520 may be substantially flat. Accordingly, the second refractive layer 520 may provide a flat surface on a layer (for example, the window 600) disposed thereon.

In an embodiment, the second refractive index of the second refractive layer 520 may be greater than the first refractive index of the first refractive pattern 510. Accordingly, the light may be refracted at an interface between the first refractive pattern 510 and the second refractive layer 520. Since the second refractive index is greater than the first refractive index, light incident on the second refractive layer 520 in a lateral direction of the display device may be refracted or reflected at the interface between the first refractive pattern 510 and the second refractive layer 520, and may be emitted in front of the display device. Accordingly, the front light efficiency of the display device may increase.

In an embodiment, for example, the second refractive layer 520 may be formed through a UV curing process after an inkjet process. In an embodiment, for example, the second refractive layer 520 may include siloxane and at least one selected from zirconium oxide (ZrOx), aluminum oxide (AlOx), and titanium oxide (TiOx). These may be used alone or in combination with each other. However, the disclosure is not limited thereto.

The window 600 may be disposed on the second refractive layer 520. The window 600 may protect components of the display device from external impact and provide a display surface of the display device.

In an embodiment, for example, the window 600 may include a polymer resin such as polycarbonate (PC), polymethyl methacrylate (PMMA), polyarylate (PAR), polyethersulfone (PES), polyethylene terephthalate (PET), polyethylene naphthalate (PEN), or the like, glass, etc. These may be used alone or in combination with each other.

However, the disclosure is not limited thereto. In an embodiment, for example, the display device may further include a polarization layer. The polarization layer may be disposed on the second refractive layer 520. The polarization layer may reduce reflection of external light of the display device. For example, when external light passes through the polarization layer and is reflected from a lower portion of the polarization layer (for example, the first to third counter electrodes 211, 212, and 213), and then passes through the polarization layer again, a phase of the external light may be changed as the external light passes through the polarization layer twice. Accordingly, a phase of the reflected light is different from a phase of the incident light entering the polarization layer, so that destructive interference may occur, and the reflection of the external light is reduced, so that the visibility of the display device may be enhanced.

FIG. 5 is an enlarged view of the light control layer included in the display device of FIG. 4.

Referring to FIGS. 4 and 5, in an embodiment, the refractive opening RO may be one of the first refractive opening RO1, the second refractive opening RO2, and the third refractive opening RO3 of FIG. 4.

The first refractive pattern 510 may have a bottom surface in contact with the upper surface of the thin film encapsulation layer 300 and a side surface exposed by the refractive opening RO. An inclination angle AN of the side surface with respect to the bottom surface of the first refractive pattern 510 may be about 650 or greater and about 90° or less.

When the inclination angle AN is less than about 65°, the light incident on the second refractive layer 520 may not be totally reflected from the side surface of the first refractive pattern 510.

When the inclination angle AN exceeds about 90°, an undercut may not be formed. Accordingly, the light incident on the second refractive layer 520 may be emitted toward the side surface of the display device.

Accordingly, in an embodiment, the inclination angle AN may be about 65° or greater and about 900 or less, such that the light emitted from the light emitting layers 201, 202, and 203 of the light emitting elements LD1, LD2, and LD3 may be totally reflected from the side surface of the first refractive pattern 510.

When an angle, a pattern, or the like of the first refractive pattern 510 is fixed, the light efficiency may be enhanced as a first thickness TK1 of the first refractive pattern 510 increases. However, as the first thickness TK1 of the first refractive pattern 510 increases, a flow of a material forming the second refractive layer 520 may be hindered, resulting in occurrence of an unfilled portion (that is, a non-filling phenomenon) of the material forming the second refractive layer 520.

Accordingly, a second thickness TK2 of the second refractive layer 520 may increase to prevent the occurrence of the non-filling phenomenon. However, as the second thickness TK2 of the second refractive layer 520 increases, a thickness of the display device may increase, and impact resistance characteristics may be weakened.

Hereinafter, a shape and an arrangement structure of the first refractive pattern 510, which can enhance the light efficiency of the display device and prevent the occurrence of the non-filling phenomenon, will be described in detail with reference to FIGS. 3 and 6 to 18.

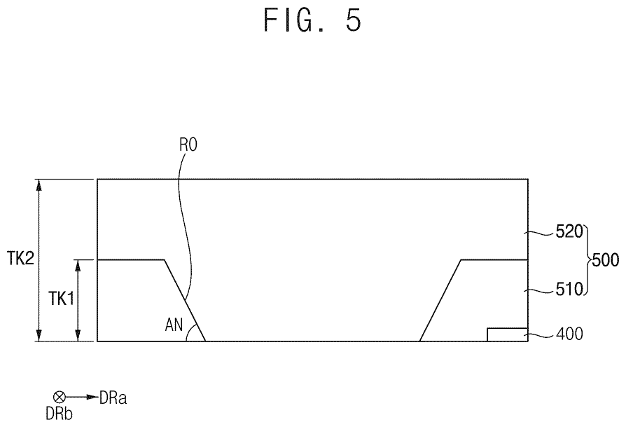

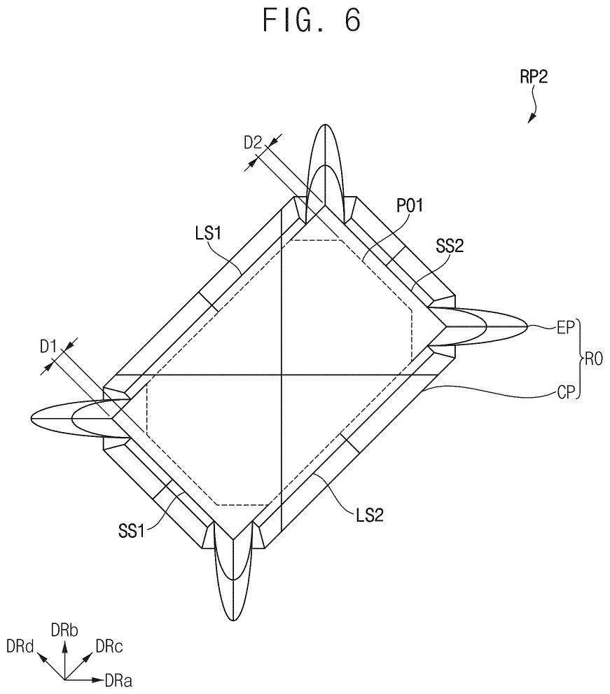

FIG. 6 is a plan view showing the refractive opening of the first refractive pattern of FIG. 3 according to an embodiment.

Referring to FIGS. 3 to 6, in an embodiment, the pixel openings (for example, the first pixel opening PO1, the second pixel opening PO2, and the third pixel opening PO3), in which the light emitting elements (for example, the first light emitting element LD1, the second light emitting element LD2, and the third light emitting element LD3) are disposed, may be defined in the display panel PA. In such an embodiment, the display panel PA may include a configuration from the substrate 100 to the sensing layer 400 as described above with reference to FIG. 4.

In an embodiment, as described above, the first refractive pattern 510 may be disposed on the display panel PA. In an embodiment, for example, where each of the plurality of pixels PX includes three sub-pixels, the first refractive pattern 510 may include a first sub-refractive pattern RP1, a second sub-refractive pattern RP2, and a third sub-refractive pattern RP3. However, the disclosure is not limited thereto. In an embodiment, for example, where each of the plurality of pixels PX includes four sub-pixels, the first refractive pattern 510 may include first to fourth sub-refractive patterns RP1, RP2, RP3, and RP4.

Hereinafter, for convenience of description, the second sub-refractive pattern RP2 overlapping the first pixel opening PO1 will be mainly described.

In an embodiment, the first pixel opening PO1 may be located inside the refractive opening RO of the second sub-refractive pattern RP2 in the plan view. In such an embodiment, the size of the refractive opening RO may be larger than the size of the first pixel opening PO1 when viewed in the plan view.

In an embodiment, when viewed in the plan view, the first pixel opening PO1 may have a polygonal shape. In an embodiment, for example, when viewed in the plan view, the first pixel opening PO1 may have a rectangular shape in which a corner portion is chamfered. The corner portion may be chamfered in a straight line or a curved line. However, the disclosure is not limited thereto. In an embodiment, for example, when viewed in the plan view, the first pixel opening PO1 may have a circular shape, an elliptical shape, or the like.

In an embodiment, for example, when viewed in the plan view, the shape of the refractive opening RO of the second sub-refractive pattern RP2 may be similar to the shape of the first pixel opening PO1. However, the disclosure is not limited thereto. In an embodiment, for example, when viewed in the plan view, the shape of the refractive opening RO of the second sub-refractive pattern RP2 may be different from the shape of the first pixel opening PO1.

In an embodiment, when viewed in the plan view, the shape of the refractive opening RO of the second sub-refractive pattern RP 2 may include a center portion CP and a peripheral portion EP.

In an embodiment, the center portion CP of the refractive opening RO of the second sub-refractive pattern RP2 may overlap the pixel opening in which the light emitting element is disposed on the display panel PA.

In an embodiment, the center portion CP of the refractive opening RO of the second sub-refractive pattern RP2 may have a quadrangular shape having a first long side LS1, a second long side LS2 opposite to the first long side LS1, a first short side SS1 crossing the first long side LS1 and the second long side LS2, and a second short side SS2 crossing the first short side SS1.

In an embodiment, as described above, the pixel opening may also have a quadrangular shape having a long side parallel to the first long side LS1 and the second long side LS2 and a short side parallel to the first short side SS1 and the second short side SS2.

In an embodiment, the peripheral portion EP of the refractive opening RO of the second sub-refractive pattern RP2 may extend from a vertex of the center portion CP. In an embodiment, for example, the peripheral portion EP may extend in different directions from the vertex of the center portion CP.

In a case of a display device according to a comparative example, when viewed in the plan view, the shape of the refractive opening of the first refractive pattern 510 may include only the center portion CP That is, when viewed in the plan view, the shape of the refractive opening of the first refractive pattern 510 according to the comparative example may not include the peripheral portion EP. In this case, a corner of the refractive opening of the first refractive pattern 510 according to the comparative example may be close to a round shape. As the corners are rounded, a pixel size increases, and filling characteristics (capillary pressure) may thus be reduced. Accordingly, in process of forming the second refractive layer 520 on the first refractive pattern 510, the non-filling phenomenon in which a periphery of the refractive opening is not filled may occur.

In the display device according to embodiments, since the refractive opening RO of the second sub-refractive pattern RP2 further includes the peripheral portion EP extending from the center portion CP, the non-filling phenomenon may be effectively prevented.

In such an embodiment, the filling characteristics may increase as a width of the peripheral portion EP decreases. In addition, the filling characteristics may increase as a length of the peripheral portion EP increases. In an embodiment, for example, the width of the peripheral portion EP may be about 0 micrometer (m) or greater, and the length of the peripheral portion EP may be about 0 μm or greater and about 4 μm or less. However, the disclosure is not limited thereto.

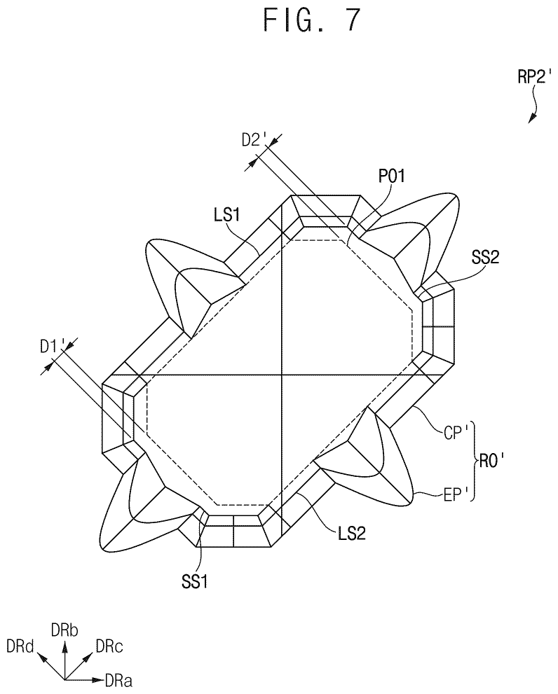

FIG. 7 is a plan view illustrating a refractive opening of a first refraction pattern of FIG. 3 according to another embodiment.

Referring to FIGS. 6 and 7, a refractive opening RO′ of a second sub-refractive pattern RP2′ of FIG. 7 may have a shape different from that of the refractive opening RO of the second sub-refractive pattern RP2 of FIG. 6.

Referring to FIGS. 3 to 5 and 7, for example, the first pixel opening PO1 may be located inside the refractive opening RO′ of the second sub-refractive pattern RP2′ when viewed in the plan view. In other words, a size of the on-plane refractive opening RO′ may be larger than the size of the first pixel opening PO1 when viewed in the plan view.

In an embodiment, for example, when viewed in the plan view, a shape of the refractive opening RO′ of the second sub-refractive pattern RP2′ may be similar to the shape of the first pixel opening PO1. However, the disclosure is not limited thereto. In an embodiment, for example, when viewed in the plan view, the shape of the refractive opening RO′ of the second sub-refractive pattern RP2′ may be different from the shape of the first pixel opening.

In an embodiment, when viewed in the plan view, the shape of the refractive opening RO′ of the second sub-refractive pattern RP2′ may include a center portion CP′ and a peripheral portion EP′.

In an embodiment, the center portion CP′ of the refractive opening RO′ of the second sub-refractive pattern RP2′ may overlap the pixel opening in which the light emitting element is disposed on the display panel PA.

In an embodiment, the center portion CP′ of the refractive opening RO′ of the second sub-refractive pattern RP2′ may have a quadrangular shape having a first long side LS1, a second long side LS2 opposite to the first long side LS1, a first short side SS1 crossing the first long side LS1 and the second long side LS2, and a second short side SS2 crossing the first short side SS1.

In an embodiment, as described above, the pixel opening may also have a quadrangular shape having a long side parallel to the first long side LS1 and the second long side LS2 and a short side parallel to the first short side SS1 and the second short side SS2.

In an embodiment, the peripheral portion EP′ of the refractive opening RO′ of the second sub-refractive pattern RP2′ may extend from a side of the center portion CP′. For example, the peripheral portion EP′ may extend in different directions from the side of the center portion CP′.

As illustrated in FIGS. 1, 3, 6, and 7, in an embodiment, the refractive opening RO according to the embodiment shown in FIG. 6 and the refractive opening RO′ according to second embodiment shown in FIG. 7 may be alternately located.

In an embodiment, the refractive opening RO according to the embodiment shown in FIG. 6 and the refractive opening RO′ according to the embodiment shown in FIG. 7 may be alternately located along a first direction DRa. However, the disclosure is not limited thereto. In an embodiment, the refractive opening RO according to the embodiment shown in FIG. 6 and the refractive opening RO′ according to the embodiment shown in FIG. 7 may be alternately located along a second direction DRb.

In an embodiment, the display panel PA may include a first pixel and a second pixel spaced apart from each other. The first pixel may include first to third sub-pixels that emit light having different colors, respectively, and the second pixel may include fourth to sixth sub-pixels that emit light having different colors, respectively. As illustrated in FIG. 3, the first sub-refractive pattern RP1, the second sub-refractive pattern RP2, and the third sub-refractive pattern RP3, which respectively overlap the first to third sub-pixels, may have shapes in which the peripheral portion EP extends from the vertex of the center portion CP. The first sub-refractive pattern RP1, the third sub-refractive pattern RP3, and the fourth sub-refractive pattern RP4, which respectively overlap the fourth to sixth sub-pixels, may have shapes in which the peripheral portion EP extends from the side of the center portion CP.

In a case of the display device according to a comparative example, the refractive opening of the first refractive pattern 510 may have one shape when viewed in the plan view. In such a comparative example, only the refractive opening RO according to the embodiment shown in FIG. 6 or the refractive opening RO′ according to the embodiment shown in FIG. 7 may be located. In this case, a part where a distance between the light emitting element and the first refractive pattern 510 increases may be formed according to a direction of the peripheral portion EP, and thus the luminance may decrease according to an azimuth angle.

In the display device according to a comparative example, the refractive openings RO and RO′ of the second sub-refractive pattern RP2 having different shapes may be alternately located. In such a comparative example, the refractive openings may be alternately located for each of the sub-pixels. In this case, in a case of the first refractive pattern 510 overlapping the sub-pixel having a rectangular shape, a color separation phenomenon may occur as compared with the first refractive pattern 510 overlapping another sub-pixel SP having a shape close to a square.

However, in the display device according to embodiments of the disclosure, the refractive openings RO and RO′ of the second sub-refractive pattern RP2 having different shapes may be alternately located, and in the refractive openings RO and RO′ overlapping each of the plurality of pixels PX, a part in which the peripheral portion EP extends from the center portion CP may be the same as a side (or vertex). Accordingly, the reduction of the luminance according to the azimuth angle may be effectively prevented, and the occurrence of the color separation phenomenon may be effectively prevented. That is, azimuth dependency may be improved.

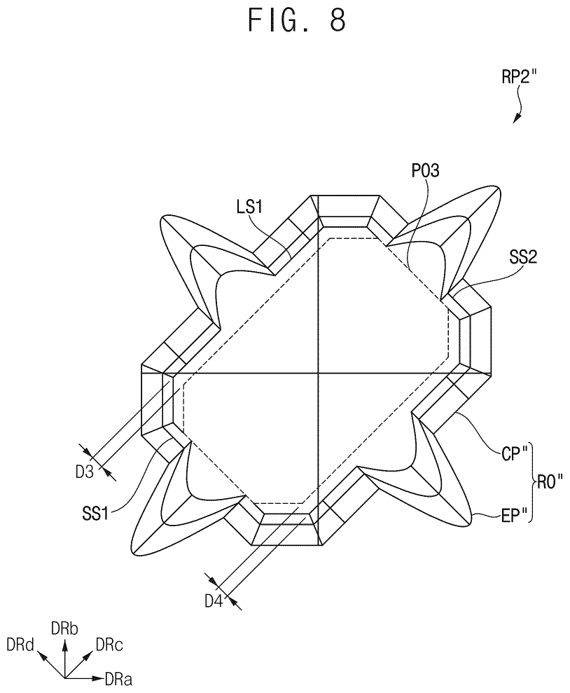

FIG. 8 is a plan view illustrating a refractive opening of a first refraction pattern of FIG. 3 according to another embodiment.

Referring to FIGS. 6 to 8, the refractive opening RO″ of the second sub-refractive pattern RP2″ of FIG. 8 may be different from the refractive opening RO of the second sub-refractive pattern of FIG. 6 and the refractive opening RO′ of the second sub-refractive pattern RP2′ of FIG. 7 only in shape and overlapping pixel opening (for example, the first pixel opening PO1 or the third pixel opening PO3).

Referring to FIGS. 3 to 5 and 8, for example, the third pixel opening PO3 may be located inside the refractive opening RO″ of the second sub-refractive pattern RP2″ when viewed in the plan view. In other words, the size of the refractive opening RO″ may be larger than the size of the third pixel opening PO3 when viewed in the plan view.

In an embodiment, for example, when viewed in the plan view, a shape of the refractive opening RO″ of the second sub-refractive pattern RP2″ may be similar to the shape of the third pixel opening PO3. However, the disclosure is not limited thereto. In an embodiment, for example, when viewed in the plan view, the shape of the refractive opening RO″ of the second sub-refractive pattern RP2″ may be different from the shape of the third pixel opening PO3.

In an embodiment, when viewed in the plan view, the shape of the refractive opening RO″ of the second sub-refractive pattern RP2″ may include a center portion CP″ and a peripheral portion EP″.

In an embodiment, the center portion CP″ of the refractive opening RO″ of the second sub-refractive pattern RP2″ may overlap the pixel opening in which the light emitting element is disposed on the display panel PA.

In an embodiment, the center portion CP″ of the refractive opening RO″ of the second sub-refractive pattern RP2″ may have a quadrangular shape having a first long side LS1, a second long side LS2 opposite to the first long side LS1, a first short side SS1 crossing the first long side LS1 and the second long side LS2, and a second short side SS2 crossing the first short side SS1.

In such an embodiment, as described above, the pixel opening may also have a quadrangular shape having a long side parallel to the first long side LS1 and the second long side LS2 and a short side parallel to the first short side SS1 and the second short side SS2.

In an embodiment, the peripheral portion EP″ of the refractive opening RO″ of the second sub-refractive pattern RP2″ may extend from the side of the center portion CP″. In an embodiment, for example, the peripheral portion EP″ may extend in different directions from the side of the center portion CP″. However, the disclosure is not limited thereto. In an embodiment, for example, similar to that illustrated in FIG. 6, the peripheral portion EP″ may extend in different directions from the vertex of the center portion CP″.

As illustrated in FIGS. 6 and 7, in an embodiment, the center portion CP or CP′ of the refractive opening RO or RO′ may extend in a direction parallel to the first long side LS1 and the second long side LS2. In this case, the center portion CP or CP′ of the refractive opening RO or RO′ may be longer than the center portion CP″ of the refractive opening RO″ illustrated in FIG. 8 in a direction parallel to a third direction DRc between the first direction DRa and the second direction DRb.

In an embodiment, when viewed in the plan view, a minimum distance (that is, a first distance D1 or D1′) between a side of the pixel opening adjacent to the first short side SS1 and the first short side SS1 in the shape of the pixel opening may be equal to a minimum distance (that is, a second distance D2 or D2′) between a side of the pixel opening adjacent to the second short side SS2 and the second short side SS2 in the shape of the pixel opening.

As illustrated in FIGS. 8, in another embodiment, the center portion CP″ of the refractive opening RO″ may extend in a direction parallel to the first short side SS1 and the second short side SS2. In this case, the center portion CP″ of the refractive opening RO″ may be longer than the center portion CP or CP′ of the refractive opening RO or RO′ illustrated in FIGS. 6 and 7 in a direction parallel to a fourth direction DRd crossing the third direction DRc. For example, the fourth direction DRd may be perpendicular to the third direction DRc.

In another embodiment, when viewed in the plan view, a minimum distance (that is, a third distance D3) between a side of the pixel opening adjacent to the first long side LS1 and the first long side LS1 in the shape of the pixel opening may be equal to a minimum distance (that is, a fourth distance D4) between a side of the pixel opening adjacent to the second long side LS2 and the second long side LS2 in the shape of the pixel opening.

In a case of the display device according to a comparative example, the refractive opening of the first refractive pattern 510 may not be located symmetrically with respect to the pixel opening. In such a comparative example, when viewed in the plan view, the minimum distance (that is, the first distance D1 or D1′) between the side of the pixel opening adjacent to the first short side SS1 and the first short side SS2 in the shape of the pixel opening and the minimum distance (that is, the second distance D2 or D2′) between the side of the pixel opening adjacent to the second short side SS2 and the second short side SS2 in the shape of the pixel opening, which are illustrated in FIGS. 6 and 7, may be different from each other, and the minimum distance (that is, the third distance D3) between the side of the pixel opening adjacent to the first long side LS1 and the first long side LS1 in the shape of the pixel opening, which is illustrated in FIG. 8, and the minimum distance (that is, the fourth distance D4) between the side of the pixel opening adjacent to the second short side LS2 and the second short side LS2 in the shape of the pixel opening, which is illustrated in FIG. 8, may be different from each other. In this case, a luminance difference may occur for each location due to luminance asymmetry according to the azimuth angle.

However, in the display device according to embodiments of the disclosure, the refractive opening RO, RO′, or RO″ of the first refractive pattern 510 may be located symmetrically with respect to the pixel opening PO1 or PO3. Accordingly, as the symmetry of the luminance increases according to the azimuth angle, the luminance difference for each position may decrease.

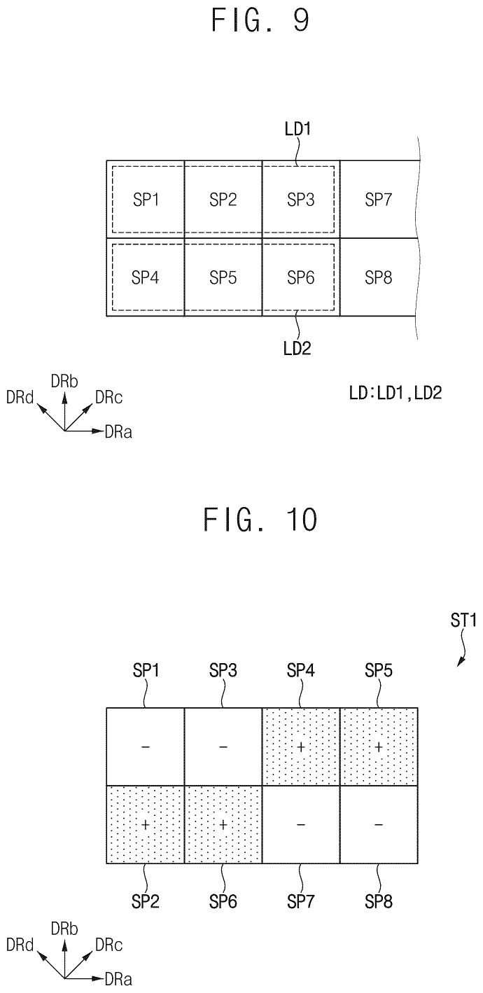

FIGS. 9 to 18 are views illustrating an arrangement structure of refractive openings of the first refractive pattern.

Referring to FIGS. 1, 3, 4, and 6 to 9, in an embodiment, the display panel PA may include a plurality of sub-pixels (for example, first to eighth sub-pixels SP1, SP2, SP3, SP4, SP5, SP6, SP7, and SP8) with the pixel opening having a polygonal shape with long sides and short sides. In an embodiment, for example, the first to third sub-pixels SP1, SP2, and SP3 may be first light emitting element D1 that emits light of the first color, and the fourth to sixth sub-pixels SP4, SP5, and SP6 may be a second light emitting element LD2 that emits light of the second color. However, the disclosure is not limited thereto. In an embodiment, for example, where only a light emitting element that emits green light has a polygonal shape having long sides and short sides, the plurality of sub-pixels may all mean light emitting elements that emit the green light.

In an embodiment, each of the plurality of sub-pixels may overlap the first refractive pattern 510 when viewed in the plan view. As described above, when viewed in the plan view, the shape of the first refractive pattern 510 may include the center portion CP and the peripheral portion EP. In an embodiment, when viewed in the plan view, a shape of the center portion CP, CP′, or CP″ of the plurality of refractive openings (for example, RO, RO′, or RO″) overlapping each of the plurality of sub-pixels may be repeatedly arranged in a unit of 4×2 matrix, that is, arranged in a repeating unit of 4×2 matrix.

Referring to FIGS. 6 to 8 and 10, in an embodiment, when viewed in the plan view, the center portion CP, CP′ or CP″, which is located in first low and first column and fourth column, and in second row and second column and third column, may extend in a direction parallel to the long side of the shape of the pixel opening PO1 or PO3 as shown in FIGS. 6 and 7 (‘−’ in FIG. 10), and the center portion CP, CP′ or CP″, which is located in first row and second column and third column, and in second row and first column and fourth column, may extend in a direction parallel to the short side of the shape of the pixel opening PO1 or PO3 as shown in FIG. 8 (‘+’ in FIG. 10).

In an embodiment, when viewed in the plan view, the minimum distance (that is, the first distance D1 or D1′, or the third distance D3) between the side of the pixel opening adjacent to the first short side SS1 and the first short side SS1 in the shape of the pixel opening PO1 or PO3 may be equal to the minimum distance (that is, the second distance D2 or D2′, or the fourth distance D4) between the side of the pixel opening adjacent to the second short side SS2 and the second short side SS2 in the shape of the pixel opening PO1 or PO3.

However, the disclosure is not limited thereto. In an embodiment, for example, the refractive opening may be asymmetric with respect to the pixel opening.

In an embodiment, as shown in FIG. 10, when viewed in the plan view, the center portion CP, CP′, or CP″ may be disposed from a shape (‘−’ in FIG. 10) extending in a direction parallel to the long side of the shape of the pixel opening PO1 or PO3 in the repeating unit of 4×2 matrix, but not being limited thereto. Alternatively, the center portion CP, CP′, or CP″ may be disposed from a shape (‘+’ in FIG. 10) extending in a direction parallel to the short side of the shape of the pixel opening PO1 or PO3 in the repeating unit of 4×2 matrix when viewed in the plan view.

Referring to FIG. 11, in an embodiment, as described above, when viewed in the plan view, the shape (‘x’ in FIG. 11) in which the peripheral portion EP extends from the side of the center portion CP and the shape (‘+’ in FIG. 11) in which the peripheral portion EP extends from the vertex of the center portion CP may be alternately located in the first direction DRa.

However, the disclosure is not limited thereto. In an embodiment, as described above, when viewed in the plan view, the shapes (‘x’ or ‘+’ in FIG. 11) may be alternately located in the second direction DRb.

In an embodiment, when viewed in the plan view, as shown in FIG. 11, the peripheral portion EP may be disposed from the shape (‘x’ in FIG. 11) extending from the side of the center portion CP in the repeating unit of 4×2 matrix, but not being limited thereto. Alternatively, the peripheral portion EP may be disposed from the shape (‘+’ in FIG. 11) extending from the vertex of the center portion CP in the repeating unit of 4×2 matrix.

A first arrangement structure ST1 of FIG. 10 and a second arrangement structure ST2 of FIG. 11 may be combined with each other so that the first refractive pattern (for example, the first refractive pattern 510 of FIG. 3) may be disposed as a third arrangement structure ST3 of FIG. 12.

Referring to FIGS. 6 to 8 and FIG. 13, in an embodiment, when viewed in the plan view, the shape (that is, ‘-’ in FIG. 10) in which the center portion CP, CP′, or CP″ extends in a direction parallel to the long side of the shape of the pixel opening PO1 or PO3, and the shape (that is, ‘+’ in FIG. 10) in which the center portion CP, CP′, or CP″ extends in a direction parallel to the short side of the shape of the pixel opening PO1 or PO3 may be alternately located in the first direction DRa.

In an embodiment, when viewed in the plan view, the minimum distance (that is, the first distance D1 or D1′, or the third distance D3) between the side of the pixel opening adjacent to the first short side SS1 and the first short side SS1 in the shape of the pixel opening PO1 or PO3 may be equal to the minimum distance (that is, the second distance D2 or D2′, or the fourth distance D4) between the side of the pixel opening adjacent to the second short side SS2 and the second short side SS2 in the shape of the pixel opening PO1 or PO3.

However, the disclosure is not limited thereto. In an embodiment, for example, the refractive opening may be asymmetric with respect to the pixel opening.

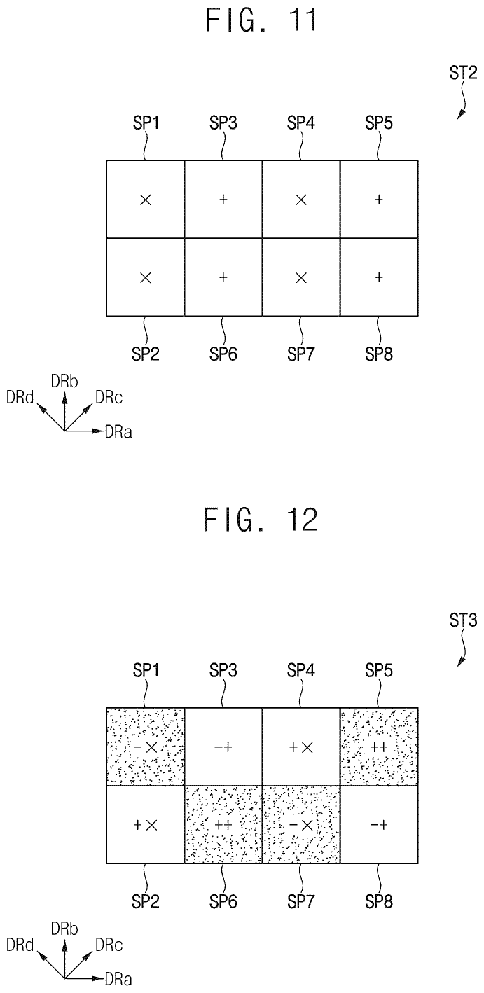

In an embodiment, as shown in FIG. 13, when viewed in the plan view, the center portion CP, CP′, or CP″ may be disposed from the shape (‘−’ in FIG. 10) extending in a direction parallel to the long side of the shape of the pixel opening PO1 or PO3 in the repeating unit of 4×2 matrix, but not being limited thereto. Alternatively, the center portion CP, CP′, or CP″ may be disposed from the shape (‘+’ in FIG. 10) extending in a direction parallel to the short side of the shape of the pixel opening PO1 or PO3 in the repeating unit of 4×2 matrix.

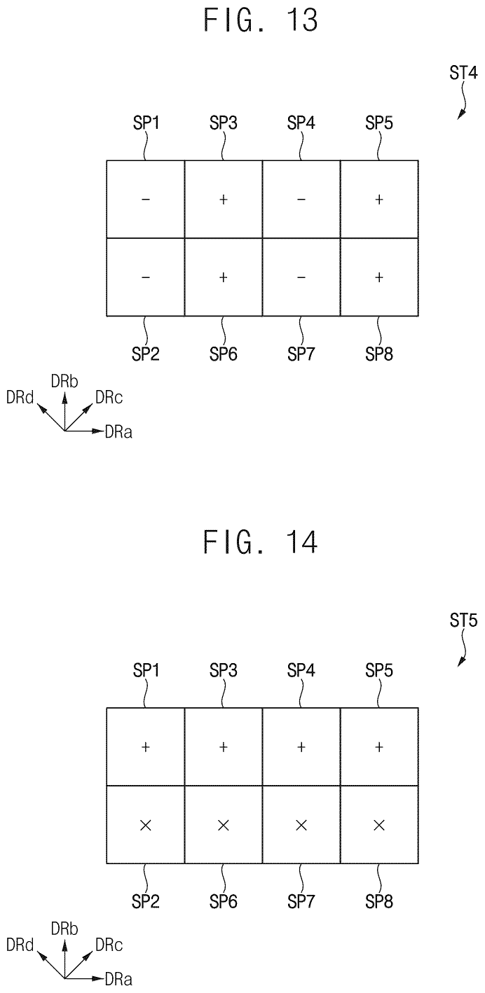

Referring to FIG. 14, as described above, when viewed in the plan view, the shape (‘x’ in FIG. 11) in which the peripheral portion EP extends from the side of the center portion CP and the shape (‘+’ in FIG. 11) in which the peripheral portion EP extends from the vertex of the center portion CP may be alternately located in the first direction DRa.

However, the disclosure is not limited thereto. As described above, when viewed in the plan view, the shapes (‘x’ or ‘+’ in FIG. 11) may be alternately located in the first direction DRa.

In an embodiment, when viewed in the plan view, as shown in FIG. 14 that the peripheral portion EP is disposed from the shape (‘+’ in FIG. 11) extending from the vertex of the center portion CP in the repeating unit of 4×2 matrix, but not being limited thereto. Alternatively, the peripheral portion EP may be disposed from the shape (‘x’ in FIG. 11) extending from the side of the center portion CP in the repeating unit of 4×2 matrix.

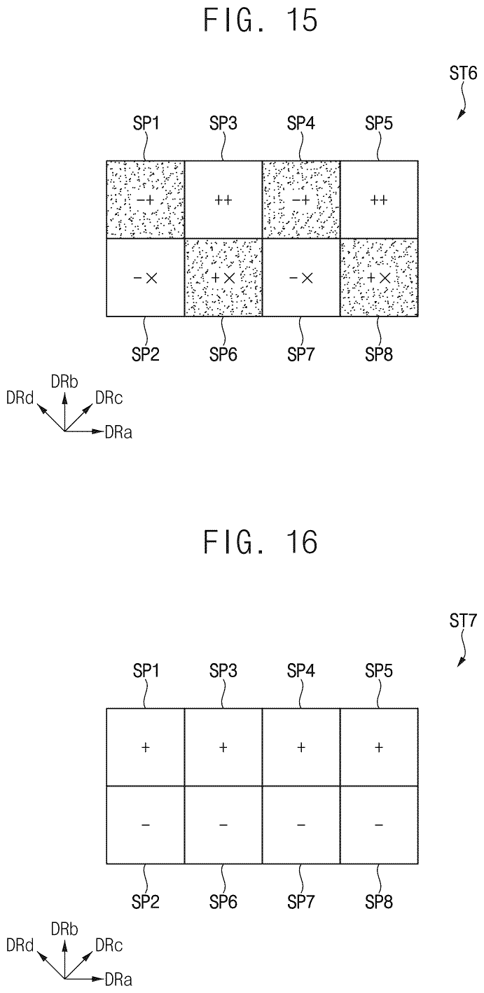

A fourth arrangement structure ST4 of FIG. 13 and a fifth arrangement structure ST5 of FIG. 14 may be combined with each other so that the first refractive pattern (for example, the first refractive pattern 510 of FIG. 3) may be disposed as a third arrangement structure ST6 of FIG. 15.

Referring to FIGS. 6 to 8 and FIG. 16, in an embodiment, when viewed in the plan view, a shape (that is, ‘−’ in FIG. 10) in which the center portion CP, CP′, or CP″ extends in a direction parallel to the long side of the shape of the pixel opening PO1 or PO3, and a shape (that is, ‘+’ in FIG. 10) in which the center portion CP, CP′, or CP″ extends in a direction parallel to the short side of the shape of the pixel opening PO1 or PO3 may be alternately located in the second direction DRb.

In an embodiment, when viewed in the plan view, the minimum distance (that is, the first distance D1 or D1′, or the third distance D3) between the side of the pixel opening adjacent to the first short side SS1 and the first short side SS1 in the shape of the pixel opening PO1 or PO3 may be equal to the minimum distance (that is, the second distance D2 or D2′, or the fourth distance D4) between the side of the pixel opening adjacent to the second short side SS2 and the second short side SS2 in the shape of the pixel opening PO1 or PO3.

However, the disclosure is not limited thereto. In an embodiment, for example, the refractive opening may be asymmetric with respect to the pixel opening.

In an embodiment, as shown in FIG. 16, when viewed in the plan view, the center portion CP, CP′, or CP″ may be disposed from the shape (‘+’ in FIG. 10) extending in a direction parallel to the short side of the shape of the pixel opening PO1 or PO3 in a repeating unit of 2×2 matrix, but not being limited thereto. Alternatively, the center portion CP, CP′, or CP″ may be disposed from the shape (‘−’ in FIG. 10) extending in a direction parallel to the long side of the shape of the pixel opening PO1 or PO3 in the repeating unit of 2×2 matrix.

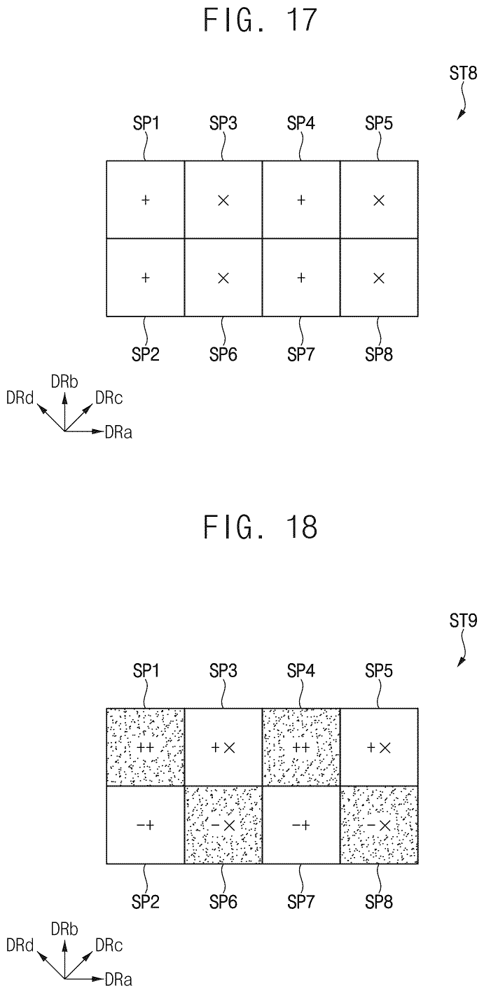

Referring to FIG. 17, as described above, when viewed in the plan view, the shape (‘x’ in FIG. 11) in which the peripheral portion EP extends from the side of the center portion CP and the shape (‘+’ in FIG. 11) in which the peripheral portion EP extends from the vertex of the center portion CP may be alternately located in the first direction DRa.

However, the disclosure is not limited thereto. In an embodiment, as described above, when viewed in the plan view, the shapes (‘x’ or ‘+’ in FIG. 11) may be alternately located in the second direction DRb.

In an embodiment, when viewed in the plan view, as shown in FIG. 17, the peripheral portion EP is disposed from the shape (‘+’ in FIG. 11) extending from the vertex of the center portion CP in the repeating unit of 2×2 matrix, but not being limited thereto. Alternatively, the peripheral portion EP may be disposed from the shape (‘x’ in FIG. 11) extending from the side of the center portion CP in the repeating unit of 2×2 matrix.

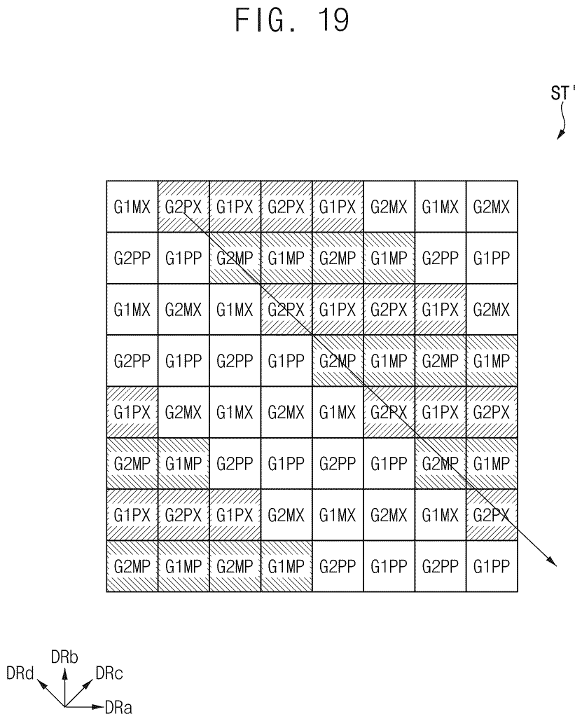

A seventh arrangement structure ST7 of FIG. 16 and an eighth arrangement structure ST8 of FIG. 17 may be combined with each other so that the first refractive pattern (for example, the first refractive pattern 510 of FIG. 3) may be disposed as a ninth arrangement structure ST9 of FIG. 18 in the repeating unit of 2×2 matrix.

FIG. 19 is a view illustrating an arrangement structure of refractive openings of a first refractive pattern according to a comparative example.

Referring to FIG. 19, in a case of the display device according to a comparative example, the arrangement structure is diagonally repeated so that the diagonal mura may be visually recognized.

However, in a case of the display device according to embodiments of the disclosure, as the shapes of FIGS. 6 to 8 and the arrangement structures of FIGS. 10 to 18 are provided, the repeated arrangement structure may not appear repeatedly in a diagonal direction. Accordingly, the generation of the diagonal mura can be effectively prevented.

Embodiments of the invention may be applied to a display device and an electronic device including the display device such as a high-resolution smart phone, a cell phone, a smart pad, a smart watch, a tablet personal computer (PC), a navigation system for a vehicle, a television, a computer monitor, a notebook, and/or the like, for example.

The invention should not be construed as being limited to the embodiments set forth herein. Rather, these embodiments are provided so that this disclosure will be thorough and complete and will fully convey the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims. Moreover, the embodiments or parts of the embodiments may be combined in whole or in part without departing from the scope of the invention.

What is claimed is:

1. A display device comprising:
a display panel;
a first refractive pattern disposed on the display panel, wherein the first refractive pattern has a first refractive index, has a planar shape including a center portion and a peripheral portion, and defines a plurality of refractive openings, in which a first refractive opening whose peripheral portion extends from a side of the center portion and a second refractive opening whose peripheral portion extends from a vertex of the center portion are alternately arranged; and
a second refractive layer disposed on the first refractive pattern, wherein the second refractive layer has a second refractive index less than the first refractive index.

2. The display device of claim 1, wherein the first refractive opening and the second refractive opening are alternately arranged in a first direction.

3. The display device of claim 1, wherein the first refractive opening and the second refractive opening are alternately arranged in a second direction crossing a first direction.

4. The display device of claim 1, wherein,
the display panel includes a first pixel disposed on a substrate and a second pixel disposed on the substrate and spaced apart from the first pixel,
the first pixel includes first to third sub-pixels which emit light having different colors, respectively,
the second pixel includes fourth to sixth sub-pixels which emit light having different colors, respectively,
each of the first to third sub-pixels overlaps the first refractive opening, and
each of the fourth to sixth sub-pixels overlaps the second refractive opening.

5. The display device of claim 1, wherein,
a pixel opening, in which a light emitting element is disposed, is defined in the display panel,
the center portion of the plurality of refractive openings has a polygonal shape including a first long side, a second long side opposite to the first long side, a first short side crossing the first long side and the second long side, and a second short side opposite to the first short side, and
the center portion of the plurality of refractive openings extends in a direction parallel to an extension direction of the first long side and the second long side.

6. The display device of claim 5, wherein a minimum distance between a third short side of the pixel opening adjacent to the first short side of the center portion of the plurality of refractive openings in a planar shape of the pixel opening and the first short side of the center portion in the planar shape of the pixel opening is equal to a minimum distance between a fourth short side of the pixel opening adjacent to the second short side of the center portion of the plurality of refractive openings in the planar shape of the pixel opening and the second short side of the center portion of the plurality of refractive openings.

7. The display device of claim 1, wherein,
a pixel opening, in which a light emitting element is disposed, is defined in the display panel,
the center portion of the plurality of refractive openings overlaps the pixel opening,
the center portion of the plurality of refractive openings has a polygonal shape including a first long side, a second long side opposite to the first long side, a first short side crossing the first long side and the second long side, and a second short side opposite to the first short side, and
the center portion of the plurality of refractive openings extends in a direction parallel to an extension direction of the first short side and the second short side.

8. The display device of claim 7, wherein a minimum distance between a third long side of the pixel opening adjacent to the first long side of the center portion of the plurality of refractive openings in the planar shape of the pixel opening and the first long side of the center portion in the planar shape of the pixel opening is equal to a minimum distance between a fourth long side of the pixel opening adjacent to the second long side of the center portion of the plurality of refractive openings in the planar shape of the pixel opening and the second long side of the center portion of the plurality of refractive openings.

9. The display device of claim 1, wherein,
a pixel opening, in which a light emitting element is disposed, is defined in the display panel,
a planar shape of the pixel opening is a polygonal shape with a long side and a short side,
the center portion of the plurality of refractive openings overlaps the pixel opening,
the center portion of the plurality of refractive openings has a polygonal shape including a first long side, a second long side opposite to the first long side, a first short side crossing the first long side and the second long side, and a second short side opposite to the first short side,
a shape of the center portion of the plurality of refractive openings in a plan view is arranged in a repeating unit of 4×2 matrix,
the center portion located at a first row and a first column, the center portion located at the first row and a fourth column, the center portion located at a second row and a second column, and the center portion located at the second row and a third column extend in a direction parallel to the long side of the planar shape of the pixel opening, and
the center portion located at the first row and the second column, the center portion located at the first row and the third column, the center portion located at the second row and the first column, and the center portion located at the second row and the fourth column extend in a direction parallel to the short side of the planar shape of the pixel opening.

10. The display device of claim 9, wherein,
a minimum distance between a third short side of the pixel opening adjacent to the first short side of the center portion of the plurality of refractive openings in the planar shape of the pixel opening and the first short side of the center portion in the planar shape of the pixel opening is equal to a minimum distance between a fourth short side of the pixel opening adjacent to the second short side of the center portion of the plurality of refractive openings in the planar shape of the pixel opening and the second short side of the center portion of the plurality of refractive openings, and
a minimum distance between a third long side of the pixel opening adjacent to the first long side of the center portion of the plurality of refractive openings in the planar shape of the pixel opening and the first long side of the center portion in the planar shape of the pixel opening is equal to a minimum distance between a fourth long side of the pixel opening adjacent to the second long side of the center portion of the plurality of refractive openings in the planar shape of the pixel opening and the second long side of the center portion of the plurality of refractive openings.

11. A display device comprising:
a display panel including a light emitting element, which is disposed in a pixel opening defined in the display panel, wherein the pixel opening has a planar shape with a long side and a short side;
a first refractive pattern disposed on the display panel, wherein the first refractive pattern has a first refractive index, overlaps the pixel openings, and defines a plurality of refractive openings including a center portion whose planar shape is a polygonal shape with a first long side, a second long side opposite to the first long side, a first short side crossing the first long side and the second long side, and a second short side opposite to the first short side and a peripheral portion extending from the center portion; and
a second refractive layer disposed on the first refractive pattern, wherein the second refractive layer has a second refractive index less than the first refractive index,
wherein a shape of the center portion of the plurality of refractive openings in a plan view is arranged in a repeating unit of 4×2 matrix,
the center portion located at a first row and a first column, the center portion located at the first row and a fourth column, the center portion located at a second row and a second column, and the center portion located at the second row and a third column extend in a direction parallel to the long side of the planar shape of the pixel opening, and
the center portion located at the first row and the second column, the center portion located at the first row and the third column, the center portion located at the second row and the first column, and the center portion located at the second row and the fourth column extend in a direction parallel to the short side of the planar shape of the pixel opening.

12. The display device of claim 11, wherein,
the first refractive pattern includes a first refractive opening whose peripheral portion extends from a side of the center portion and a second refractive opening whose peripheral portion extends from a vertex of the center portion in the plan view, and
the first refractive opening and the second refractive opening are alternately arranged in a first direction.

13. The display device of claim 11, wherein,
the first refractive pattern includes a first refractive opening whose peripheral portion extends from a side of the center portion and a second refractive opening whose peripheral portion extends from a vertex of the center portion in the plan view, and
the first refractive opening and the second refractive opening are alternately arranged in a second direction crossing a first direction.

14. The display device of claim 11,
wherein a minimum distance between a third short side of the pixel opening adjacent to the first short side of the center portion of the plurality of refractive openings in the planar shape of the pixel opening and the first short side of the center portion in the planar shape of the pixel opening is equal to a minimum distance between a fourth short side of the pixel opening adjacent to the second short side of the center portion of the plurality of refractive openings in the planar shape of the pixel opening and the second short side of the center portion of the plurality of refractive openings, and
wherein a minimum distance between a side of the pixel opening adjacent to the first long side of the center portion of the plurality of refractive openings in the planar shape of the pixel opening and the first long side of the center portion in the planar shape of the pixel opening is equal to a minimum distance between a side of the pixel opening adjacent to the second long side of the center portion of the plurality of refractive openings in the planar shape of the pixel opening and the second long side of the center portion of the plurality of refractive openings.

15. The display device of claim 11, wherein,
the display panel includes a first pixel disposed on a substrate and a second pixel disposed on the substrate and spaced apart from the first pixel,
the first pixel includes first to third sub-pixels which emit light having different colors, respectively,
the second pixel includes fourth to sixth sub-pixels which emit light having different colors, respectively,
the peripheral portion of the plurality of refractive openings overlapping each of the first to third sub-pixels extends from a side of the center portion, and
the peripheral portion of the plurality of refractive openings overlapping each of the fourth to sixth sub-pixels extends from a vertex of the center portion.

16. A display device comprising:
a display panel;
a first refractive pattern disposed on the display panel, wherein the first refractive pattern has a first refractive index, and defines a plurality of refractive openings including a center portion whose planar shape is a polygonal shape with a first long side, a second long side opposite to the first long side, a first short side crossing the first long side and the second long side, and a second short side opposite to the first short side and a peripheral portion extending from the center portion; and
a second refractive layer disposed on the first refractive pattern, wherein the second refractive layer has a second refractive index less than the first refractive index,
wherein a shape of the center portion of the plurality of refractive openings in a plan view is arranged in a repeating unit of 2×2 matrix,
the center portion located at a first row and a first column, and the center portion located at a second row and a second column extend in a direction parallel to an extension direction of the first long side and the second long side, and
the center portion located at the first row and the second column, and the center portion located at the second row and the first column extend in a direction parallel to an extension direction of the first short side and the second short side.

17. The display device of claim 16, wherein,
the first refractive pattern includes a first refractive opening whose peripheral portion extends from a side of the center portion and a second refractive opening whose peripheral portion extends from a vertex of the center portion in the plan view, and
the first refractive opening and the second refractive opening are alternately arranged in a first direction.

18. The display device of claim 16, wherein,
the first refractive pattern includes a first refractive opening whose peripheral portion extends from a side of the center portion and a second refractive opening whose peripheral portion extends from a vertex of the center portion in the plan view, and
the first refractive opening and the second refractive opening are alternately arranged in a second direction crossing a first direction.

19. The display device of claim 16, wherein,
a pixel opening, in which a light emitting element is disposed, is defined in the display panel,
a minimum distance between a third short side of the pixel opening adjacent to the first short side of the center portion of the plurality of refractive openings and the first short side of the center portion in the planar shape of the pixel opening is equal to a minimum distance between a fourth short side of the pixel opening adjacent to the second short side of the center portion of the plurality of refractive openings and the second short side of the center portion of the plurality of refractive openings in the planar shape of the pixel opening, and
wherein a minimum distance between a third long side of the pixel opening adjacent to the first long side of the center portion of the plurality of refractive openings and the first long side of the center portion in the planar shape of the pixel opening is equal to a minimum distance between a fourth long side of the pixel opening adjacent to the second long side of the center portion of the plurality of refractive openings and the second long side of the center portion of the plurality of refractive openings in the planar shape of the pixel opening.

20. The display device of claim 16, wherein,
the display panel includes a first pixel disposed on a substrate and a second pixel disposed on the substrate and spaced apart from the first pixel,
the first pixel includes first to third sub-pixels which emit light having different colors, respectively,
the second pixel includes fourth to sixth sub-pixels which emit light having different colors, respectively,
the peripheral portion of the plurality of refractive openings overlapping each of the first to third sub-pixels extends from a side of the center portion, and
the peripheral portion of the plurality of refractive openings overlapping each of the fourth to sixth sub-pixels extends from a vertex of the center portion.
